(19) United States
(12) Patent Application Publication
(10) Pub. No.: US 2004/0245527 A1
(43) Pub. Date: Dec. 9, 2004

(54) Terminal and thin-film transistor

(76) Inventors: Kazuhito Tsukagoshi, Saitama (JP); Iwao Yagi, Saitama (JP); Yoshinobu Aoyagi, Saitama (JP)

Correspondence Address: BIRCH STEWART KOLASCH & BIRCH, PO BOX 747, FALLS CHURCH, VA, 22040-0747, US

(21) Appl. No.: 10/808,333

(22) Filed: Mar. 25, 2004

(30) Foreign Application Priority Data
May 30, 2003 (JP) 154841/2003

(51) Int. Cl. H01L 29/04; H01L 31/036

(52) U.S. Cl. 257/77; 438/931; 257/59; 257/72

(57) ABSTRACT

Disclosed is a terminal for an organic material, which comprises a carbon nanotube to be in contact with an organic material having a 6-membered carbon ring, and a metal that is in contact with a part of the carbon nanotube. The carbon nanotube remarkably improves an electric conductivity between the organic material and the metal.

### BACKGROUND OF THE INVENTION

1. Field of the Invention

The present invention relates to a terminal comprising a metal and a carbon nanotube, and to a thin-film transistor comprising the terminal.

2. Description of the Background

Thin-film transistors comprising an organic material as a semiconductor component have heretofore been specifically highlighted. Organic materials can be more readily processed from their solutions, for example, in a mode of spin coating, dipping, thermal vapor deposition or screen printing, and therefore could be more inexpensive substitutes for inorganic materials in constructing thin-film transistors.

However, organic materials have some problems in that the carrier mobility through them is low. Therefore, various investigations has been made on them. This is described hereinunder with reference to the drawings attached hereto.

JP-A 2000-260999 discloses, as in FIG. 14, a thin-film transistor that comprises an organic/inorganic hybrid material 103 for a semiconductor channel formed between a source electrode 101 and a drain electrode 102. JP-A 2000-260999 says that the thin-film transistor enjoys the advantages of an inorganic crystalline solid and an organic material.

JP-A 2003-86805 discloses, as in FIG. 15, a thin-film transistor that comprises a source region of a source electrode 110 and a source insulation layer 111; a drain region of a drain electrode 112 and a drain insulation layer 113; a channel region of an organic semiconductor layer 114 which is formed of at least an organic semiconductor material to connect the source region and the drain region; and a gate region of a gate insulation layer 115 formed below the channel region between the source region and the drain region, a gate layer 116 formed of a semiconductor material to be below and on the same level of the source region, the gate insulation layer 115 and the drain region, and a gate electrode 117 attached to the gate layer 116. JP-A 2003-86805 says that the thin-film transistor having the constitution as in the drawing may readily form a depletion layer and an inversion layer and the carrier on the source side can be rapidly absorbed by the drain side.

Solid State Technology, Vol. 43, No. 3, pp. 63-77, March 2000 discloses, as in FIG. 16, a thin-film transistor that comprises a source electrode 121, a drain electrode 122, a pentacene thin-film transistor layer 123, an insulation layer 124, a gate layer 125, and a substrate 126. This says that, in the thin-film transistor, a film of an organic material such as pentacene is formed on a plastic substrate.

Science, Vol. 280 (Jun. 12, 1998) and JP-T 2002-512451 (the term “JP-T” as used herein means a published Japanese translation of a PCT patent application) disclose, as in FIG. 17, a thin-film transistor that comprises a current drive switch and a second circuit integrated with the current drive switch. These say that, when an voltage is applied to the source electrode 131 of the transistor and the anode 132 of LED and when a bias electrode is applied to the gate electrode 133 of the transistor, then a current flows from the source electrode 131 toward the drain electrode 135 via the semiconductor layer 134 of the transistor; and the drain electrode 135 functions also as the anode of LED, therefore the current may flow from the drain electrode 135 toward the cathode of LED through the light emission layer 139 of LED, and, as a result, the light emission layer 139 emits light in the direction of the arrow hv; an insulation layer 136 of silicon oxide and an n⁺-type silicon 137 are disposed between the semiconductor layer 134 and the gate electrode 133, and the insulation layer 138 of silicon oxide stands to separate the light emission layer 139 from the source electrode 131.

As so mentioned hereinabove, the conductivity of thin-film transistors where an organic material is used for channels is extremely low, and the problem with it is not still solved. Regarding the reason for it, Al. Appl. Phys. Lett., 78, 993 (2001) says that the contact resistance between a fine organic channel and a metal electrode face is extremely large, and almost all the voltage applied will be absorbed by that portion, and, as a result, almost no effective voltage could be applied to the channel. In that situation, therefore desired is a root solution to the problem with the conductivity of thin-film transistors where an organic material is used for channels.

### SUMMARY OF THE INVENTION

Having investigated the prior-art techniques, we, the present inventors have considered that the problem of the extremely large contact resistance in the interface between a fine organic material and a metal must be solved. If the problem of the contact resistance could be solved, then the applied voltage absorption by the interface between the organic material and metal could be prevented.

Given that situation, we, the inventors formed a metal electrode in a mode of electron beam lithography and inserted thereinto a single grain of pentacene, a type of an organic material having a 6-membered carbon ring structure, and using it, we constructed a field-effect transistor and analyzed its current-voltage curve. The field-effect transistor operated but gave a large hysteresis (FIG. 13). We, the inventors observed the interface between the metal electrode and the pentacene with an atomic force microscope, and have found that the contact between the metal electrode and the pentacene is not good and the two are not in uniform contact at the interface thereof and that the contact area in the interface is extremely small.

Through further investigations, we, the inventors have found that, for overcoming the problems with the interface between metal electrode and pentacene, a small, thin and stable substance must be used for the material for electrode, the material must ensure good contact with pentacene, and in particular, the material must ensure interfacial contact with pentacene through chemical interaction with it.

Having assiduously studied the above, we, the inventors have completed the present invention as described hereinunder.

Specifically, the invention introduces a terminal for organic material, which comprises a carbon nanotube to be in contact with an organic material having a 6-membered carbon ring, and a metal that is in contact with a part of the carbon nanotube; a thin-film transistor comprising, as an electrode thereof, a terminal that comprises a carbon nanotube to be in contact with an organic material having a 6-membered carbon ring, and a metal that is in contact with a part of the carbon nanotube; and introduces the following:

A thin-film transistor comprising at least a first electrode region, a second electrode region, and a channel formed of an organic material having a 6-membered carbon ring for electrically connecting the first electrode region and the second electrode region, wherein the first electrode region and the second electrode region each comprise a carbon nanotube that is in contact with the 6-membered carbon ring of the channel at its interface, and a metal that is in contact with a part of the carbon nanotube; the thin-film transistor wherein the carbon nanotube contains a fullerene; the thin-film transistor wherein the carbon nanotube contains a C₆₀, C₇₀, C₇₆, C₇₈, C₈₂, C₈₄ or C₉₂ fullerene; the thin-film transistor wherein the carbon nanotube has a resistance of from 10⁻⁵ to 10⁻⁴ Ωcm; the thin-film transistor wherein the channel is formed of an acene; the thin-film transistor wherein the channel is formed of a thiophene or a fullerene; the thin-film transistor wherein the channel is formed of pentacene; the thin-film transistor wherein the carbon nanotube is a multi-layered one; the thin-film transistor wherein the metal that is in contact with a part of the carbon nanotube is gold, titanium, chromium, thallium, copper, titanium, molybdenum, tungsten, nickel, palladium, platinum, silver or tin, or a combination thereof; the thin-film transistor wherein the metal that is in contact with a part of the carbon nanotube is a combination of gold and platinum; the thin-film transistor wherein the contact length between the channel and the carbon nanotube is from 1 to 10 μm; the thin-film transistor wherein the length of the carbon nanotube is from 5 to 20 μm.

In addition, the invention further introduces the following:

A thin-film transistor comprising a substrate, an insulation layer formed on the substrate, and a first electrode region, a second electrode region and a channel formed of an organic material having a 6-membered carbon ring for electrically connecting the first electrode region and the second electrode region that are all formed on the insulation layer, wherein the first electrode region and the second electrode region each comprise a carbon nanotube that is in contact with the 6-membered carbon ring of the channel at its interface, and a metal that is in contact with a part of the carbon nanotube; the thin-film transistor wherein the insulation layer is formed of an inorganic material, a polymer material or a self-organizing molecular membrane; the thin-film transistor wherein the substrate is an insulating substrate or a semiconductive substrate; the thin-film transistor wherein the first electrode region and the second electrode region have two or more carbon nanotubes each; the thin-film transistor wherein the carbon nanotube that the first electrode region has and the carbon nanotube that the second electrode region has are parallel to each other in the area in which they are in contact with the channel; and introduces the following:

A method for producing a thin-film transistor, which comprises a step of forming a first metal electrode and a second metal electrode on a substrate, a step of dispersing carbon nanotubes so as to form an electroconductive structure between the first metal electrode and the second metal electrode, a step of cutting a part of the carbon nanotubes through electric breakaway, and a step of forming a channel of an organic material on the carbon nanotubes that include the cut part thereof.

### BRIEF DESCRIPTION OF THE DRAWINGS

FIG. 1 shows a first embodiment of the thin-film transistor of the invention.

FIG. 2 shows a second embodiment of the thin-film transistor of the invention.

FIG. 3 shows a third embodiment of the thin-film transistor of the invention.

FIG. 4 shows schematic process drawings of forming a lead electrode pattern.

FIG. 5 shows a schematic view of a device with nanotubes dispersed and connected to a lead electrode.

FIG. 6 shows a relationship between a current and a gate voltage of the device of FIG. 5 under various constant voltages.

FIG. 7 shows the data of current-voltage curve relative to the gate electrode of the device of FIG. 5.

FIG. 8 shows a schematic view of electric breakaway of carbon nanotubes.

FIG. 9 shows the condition of the device of FIG. 8 with gradually-increasing voltage applied thereto.

FIG. 10 shows the distribution of the gap length of the cut part of nanotubes.

FIG. 11 shows a schematic view of an example.

FIG. 12 shows current-voltage curves of the device of FIG. 11.

FIG. 13 shows current-voltage curves of a device with a conventional metal electrode alone.

FIG. 14 shows a schematic view of a thin-film transistor disclosed in JP-A 2000-260999.

FIG. 15 shows a schematic view of a thin-film transistor disclosed in JP-A 2003-86805.

FIG. 16 shows a schematic view of a thin-film transistor disclosed in Solid Stage Technology, Vol. 43, No. 3, pp. 63-77, March 2000.

FIG. 17 shows a schematic view of a thin-film transistor disclosed in Science, Vol. 280, Jun. 12, 1998 and JP-T 2002-512451.

### BEST MODE FOR CARRYING OUT THE INVENTION

The low-contact-resistance terminal of the invention is for electric connection in batteries, electric circuits, electric appliances, etc. The thin-film transistor of the invention includes field-effect transistors. The field-effect transistor of the invention is meant to include not only metal oxide film semiconductor field-effect transistors but also more general field-effect transistors with a combination of metal electrode-insulator-semiconductor. A metal part of the electrode region as referred to in the invention may be referred to as a metal electrode, for the convenience of description.

The carbon nanotube in the invention is to better the contact between a channel and a metal and to improve the electric conductivity therebetween. Concretely, the carbon nanotube for use in the invention is such that the greater part of its composition is carbon and a major part thereof has 6-membered rings and that it has a tubular form. More concretely, the carbon nanotube in the invention is such that its 6-membered carbon ring structure is to contact with the 6-membered carbon ring structure part of a channel material at its interface, in particular through chemical interaction between them. Specifically, the 6-membered carbon ring structure of the carbon nanotube is to contact with the 6-membered carbon ring structure of a channel material at its interface in a mode of interaction of π-electrons of the two.

The electroconductivity of the carbon nanotube for use in the invention is higher than that of channel materials. Specifically, the resistance of carbon nanotube is lower than that of channels. Preferably, the carbon nanotube in the invention falls between 10⁻⁵ and 10⁻⁴ Ωcm. Since the carbon nanotube has an extremely thin and small structure, its compatibility with metal is good. Therefore, even though the contact area between the carbon nanotube and the metal adjacent thereto is small, the current flow through the metal to the carbon nanotube and to the channel adjacent to the metal is very good.

The most characteristic feature of the carbon nanotube in the invention is that it contains 6-membered carbon rings. For example, it includes carbon nanotubes, fullerene-containing carbon nanotubes, and tubular fullerenes.

The carbon nanotube in the invention may be a substance of hollow linear carbon alone having a diameter of from 1 to 50 nm. The term “tube” as referred to herein does not always mean a cylindrical form alone but may include any others such as those formed by winding up thin membranes. For example, it includes tubular shaped formed by winding up graphite membranes.

The carbon nanotube in the invention may be a multi-layered one or a single-layered one. The multi-layered carbon nanotube for use herein preferably has a diameter of from 5 to 50 nm or so and a length of from 1 to 100 μm or so, more preferably a diameter of from 10 to 20 nm or so and a length of from 2 to 15 μm or so. The single-layered carbon nanotube for use herein preferably has a diameter of from 0.6 to 5 nm or so and a length of from 1 to 100 μm or so, more preferably a diameter of from 0.6 to 5 nm or so and a length of from 2 to 15 μm or so. The carbon nanotube may have an armchair-like structure or a spiral structure. Needless-to-say, the cross section of the carbon nanotube for use in the invention may not always be true circular but may be oval or the like.

The fullerene-containing carbon nanotube for use herein is meant to indicate a carbon nanotube having a fullerene on the outside or inside thereof. Fullerene has at least 20 carbon atoms, in which all the carbon atoms are three-coordinated or form basket-structured molecules. For example, it includes C₆₀, C₇₀, C₇₆, C₇₈, C₈₂, C₈₄ and C₉₂ fullerenes. They may be chemically modified or may contain any other atom. For example, fullerenes with any of La, Er, Gd, Ho, Nd, Y, Sc, Sc₂ or Sc₃N therein may be used herein.

Carbon nanotubes are commercially available (e.g., those from Shinku Yakin), and they maybe used in the invention directly as they are or after worked. For example, they may be worked in a mode of thermal filament plasma CVD, microwave plasma CVD, thermal CVD, or according to the method described in JP-A 2002-285335.

For processing carbon nanotubes, there is known a method of using optical tweezers. This is a technique of focusing light for aggregation of micron-size particles. According to the method, carbon nanotubes may be integrated around a channel. Since carbon nanotubes may be readily oriented toward the direction of electric field, they may be aligned in that direction.

For the channel layer in the invention, any conductive organic material having a 6-membered carbon ring structure is broadly employable herein. For example, herein usable are acenes, fullerenes, thiophenes and their derivatives. Not overstepping the sprit of the invention, acenes for use herein are not specifically defined. For example, they include pentacene, naphthalene, anthracene, tetracene, hexacene. Not also overstepping the sprit of the invention, any fullerenes are broadly usable herein that contain a 6-membered carbon ring structure capable of chemically interacting with the 6-membered carbon ring structure of carbon nanotubes. Not also overstepping the sprit of the invention, thiophenes for use herein are not specifically defined. For example, they are condensed ring-structured organic compounds having two or three condensed, 6-membered aromatic rings, in which the two ends are terminated with a 5-membered aromatic heterocyclic ring structure.

The material of the metal electrode in the invention is not specifically defined, and may be broadly any one not overstepping the sprit of the invention. For example, it includes gold (Au), titanium (Ti), chromium (Cr), thallium (Ta), copper (Cu), aluminium (Al), molybdenum (Mo), tungsten (W), nickel (Ni), palladium (Pd), platinum (Pt), silver (Ag), tin (Sn). Their combination may also be usable herein. For example, a combination of gold (Au)/titanium (Ti) is usable. The metal for the electrode may differ between the source region and the drain region. The electrode region as referred to herein is one that comprises a carbon nanotube and a metal. In addition, the electrode region is a part that is generally referred to as an electrode, and it may indicate a source region (or a source electrode) or a drain region (or a drain electrode), or may indicate both the two.

The insulation layer in the invention may be broadly any one, not overstepping the spirit of the invention. For example, herein usable are any of inorganic materials such as silicon oxide, siliconnitride, aluminiumoxide, titaniumoxide, calcium fluoride; polymer materials such as acrylic resin, epoxy resin, polyimide, Teflon (trade mark); and self-organizing molecular membranes such as aminopropylethoxysilane.

Not specifically defined, the substrate in the invention may be an insulating substrate or a semiconductive substrate. For the insulating substrate, for example, usable are silicon oxide, siliconnitride, aluminiumoxide, titaniumoxide, calcium fluoride, insulating resin such as acrylic resin or epoxy resin, polyimide, Teflon, etc. For the semiconductive substrate, for example, usable are silicon, germanium, gallium-arsenic, indium-phosphorus, silicon carbide, etc. Preferably, the substrate is planarized.

Not specifically defined, the gate electrode for use in the thin-film transistor of the invention may be broadly any one generally used in transistors of the type. For example, Al, Cu, Ti, polysilicon, silicide, and organic conductors may be used for it. For the gate insulation film, employable is an inorganic insulation film of SiO₂, SiN or the like, or an organic material such as polyimide, polyacrylonitrile.

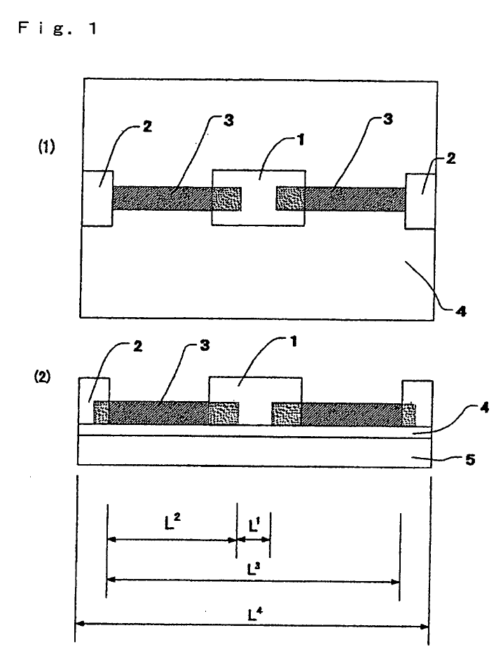

Embodiments of the invention are described hereinunder with reference to the drawings. FIG. 1 shows a transistor, one preferred embodiment of the invention, in which (2) is a cross section of (1). In this, 1 indicates a channel, 2 indicates a metal, 3 indicates a carbon nanotube, 4 indicates an insulation layer, and 5 indicates a substrate. The invention is characterized in that the metal 2 and the carbon nanotube 3 form the drain region and the source region. Concretely, the invention is characterized in that a carbon nanotube is provided between the metal and the channel, and they form an electrode region. Accordingly, even when an organic material is used for the channel material, the connection between the channel material and the electrode is good. Therefore, the invention has dramatically improved the conductivity of the parts of the transistor. In other words, the operation speed of the transistor has increased, and the characteristic fluctuation among devices has reduced.

In FIG. 1, the distance L¹ between the two carbon nanotubes adjacent to each other via a channel is preferably from more than 0 to 100 nm but not, more preferably from more than 0 to 50 nm.

In FIG. 1, the distance L² between one metal electrode 2 and the channel 1 is preferably from 1 to 10 μm, more preferably from 2 to 5 μm. Having the length, it ensures a predetermined margin and enables surer formation of a contact window that will be described hereinunder.

In FIG. 1, the length of each carbon nanotube is preferably from 5 to 20 μm, more preferably from 5 to 10 μm. Though not specifically defined herein, one carbon nanotube forms a source region and the other forms a drain region.

In FIG. 1, the distance L³ between the electrodes is preferably from 1 to 100 μm, more preferably from 5 to 10 μm. The overall width L⁴of the entire transistor may be, for example, from 0.1 to 3 mm. Needless-to-say, it may be suitably defined in accordance with the use and the object of the transistor.

In FIG. 1, the contact length between the channel and the carbon nanotube is preferably from 1 to 10 μm, more preferably from 1 to 5 μm.

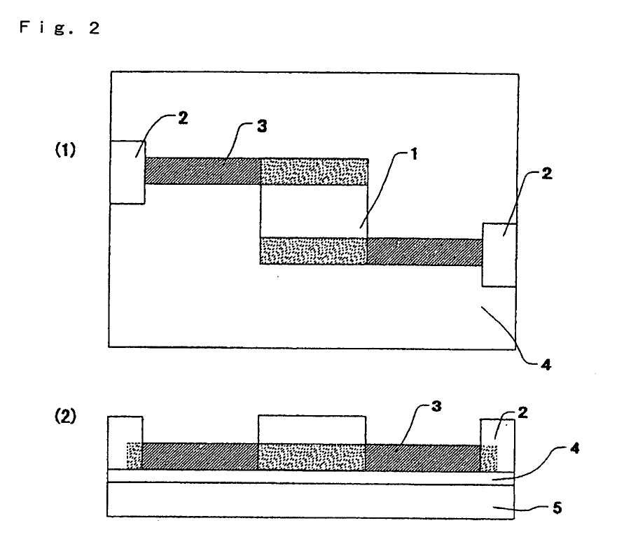

FIG. 2 shows another embodiment of the invention. The numeral references in this are the same as those in FIG. 1. This embodiment is characterized in that the carbon nanotubes 3 are aligned in parallel to each other in the channel region. As in this embodiment, the carbon nanotubes may not always be aligned in a line in the source region and the drain region. Further, the carbon nanotubes may not always be linear, but may be bent or curved.

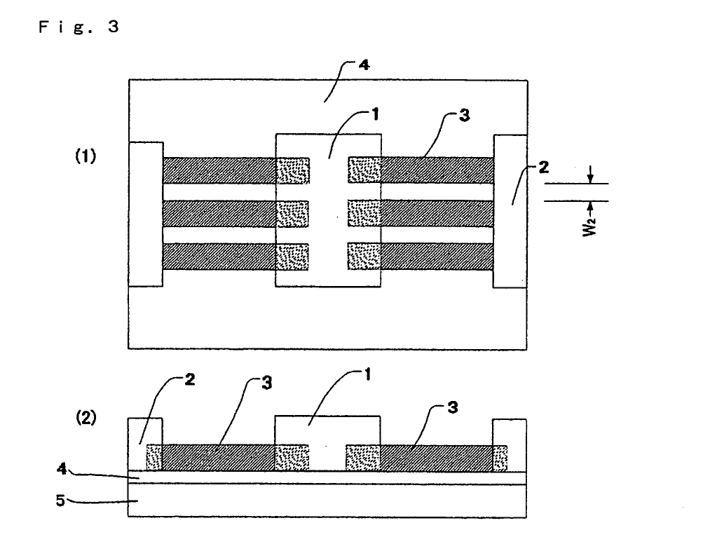

FIG. 3 shows still another embodiment with multiple carbon nanotubes aligned therein. The numeral references in this are the same as those in FIG. 1. Having such multiple carbon nanotubes therein, this embodiment enables better electron transfer through it. The number of the electrodes in this embodiment is 3 each, which, however, is not limitative. If desired, the number may be increased.

Regarding its shape, the channel is square, when seen in the direction of (1) in FIGS. 1 to 3, but this is not limitative. If desired, the channel may have any other shape. The carbon nanotube is preferably cylindrical, but this is not limitative. Its cross section may be oval. Not limited to such a cylindrical shape, the carbon nanotube may have any other shape such as that formed by winding up a thin membrane, as so mentioned hereinabove. In FIGS. 1 to 3, the carbon nanotubes are fitted to the metal vertically thereto. Needless-to-say, however, they may be fitted to the metal at any desired angle.

The transistor of the invention may be broadly employed in various electric appliances, medical appliances, etc. Concretely, it may be used for terminal connection in flexible displays, micro-organoelectronic devices, nanobio-devices, molecular sensors, etc. Needless-to-say, the invention should not be limited to these applications, and not overstepping its sprit, the invention may be broadly applied to any others.

### EXAMPLES

The present invention will be further specifically explained with reference to the following examples of the present invention. The materials, amounts, ratios, types and procedures of treatments and so forth shown in the following examples can be suitably changed unless such changes depart from the spirit of the present invention. Accordingly, the scope of the present invention should not be construed as limited to the following specific examples.

(1) Formation of Back-Gate Electrode:

A high-dope p-type Si substrate (from E & M) having a thickness of 350 μm and having a 200 nm-thick thermal oxidation film of SiO₂ on its face and back was cut with a diamond cutter into 25 mm×25 mm pieces. The substrate was doped with boron, and its resistivity is at most 0.00099 Ωcm and its carrier concentration is at least 10²⁰ cm³. A photo resist AZ-1350J (from Clariant Japan—the same shall apply hereinunder) was dropwise applied onto the thus-cut substrate. Using a spin coater (from Mikasa), this was rotated at 500 rpm for the initial 5 seconds and then at a constant rate of 3000 rpm for the next 60 seconds whereby the photoresist was made even on the surface of the substrate. Thus processed, the substrate was then dipped in a hydrogen fluoride solution (HF solution) for 3 minutes to remove the oxide film of SiO₂ on the back thereof whereby Si was exposed out on the back. The exposure of Si was confirmed through measurement of the electric resistance of the back by the use of a tester. Immediately after the confirmation, an Al layer of 10 nm thick, a Ti layer of 10 nm thick and an Au layer of 100 nm thick were deposited on the back of the substrate in that order all in a mode of vacuum evaporation. After the layer deposition thereon, the substrate was then dipped in acetone to remove the resist from its surface. Next, this was rinsed with isopropyl alcohol. After the process, the substrate was wholly heated in an oven at 250° C. for 15 minutes to thereby anneal the interface between the surface Si and Al. The Au/Ti/Al electrode thus formed on the back of the substrate according to the process serves as the back-gate metal electrode in this example.

(2) Formation of Lead Electrode:

A photoresist AZ-1350J was dropwise applied onto the surface of the 25 -mm² substrate with the back-gate electrode formed on its back in the above (1). Using a spin coater (from Mikasa), this was rotated at 500 rpm for the initial 5 seconds and then at a constant rate of 5000 rpm for the next 60 seconds whereby the photoresist was made even on the surface of the substrate (FIG. 4 (1), side view). After thus coated with the photoresist, this was exposed to light in a mode of UV lithography using a photolithographic mask and a mask aligner (MA-20, from Mikasa). Concretely, the substrate was covered with a photomask airtightly attached thereto (FIG. 4 (2), top view), and exposed to UV rays (FIG. 4(3), sideview). Next, the substrate was dipped in a developer to develop the pattern, and the pattern was transferred onto the photoresist (FIG. 4 (4)). Immediately after this step, a Ti layer of 5 nm thick, and then an Au layer of 80 nm thick were deposited on the surface of the substrate by the use of a vapor deposition chamber (from Irie Koken) (FIG. 4(5)). After the layer deposition thereon, the substrate was then dipped in acetone to remove the resist from its surface (FIG. 4(6)), and then rinsed with isopropyl alcohol. The metal electrode wire pattern thus formed on the substrate surface in this process is hereinafter referred to as “lead electrode”. The photolithographic mask used herein had four and the same 5-mm² patterns both in the lengthwise and widthwise directions, totaling 16 patterns engraved through it. Accordingly, the 25-mm² substrate having been processed as in the above had 16 and the same 5-mm² patterns all formed at a time, and this was divided into 16 pieces each having a size of 5 mm². These 5-mm² substrates with the back-gate electrode and the lead electrode formed thereon are hereinafter referred to as “chips”. In FIG. 4, 5 indicates the substrate, 14 indicates the resist, 15 indicates the photomask, and 2 indicates the metal. The photomask in FIG. 4(2) is an outline view.

(3) Formation of Address Pattern:

An electron-beam resist of polymethyl methacrylate (PMMA) was dropwise applied onto the surface of the 5-mm² chip formed in the above (2). Then, using the same spin coater as in the above (1), this was rotated at 500 rpm for the initial 5 seconds and then at a constant rate of 5000 rpm for the next 40 seconds whereby the resist was made even on the surface of the substrate. After thus coated with the electron-beam resist; the chip was put into a device for electron-beam lithography (ELS-7300 by Elionix), in which an address pattern was written on the resist. The address pattern as referred to herein is meant to indicate a lattice point pattern that comprises numerals and lattice points. The size of each numeral and lattice point was about 200 to 300 nm or so. The address pattern was written in the part of the chip not having the lead electrode. After the pattern writing, the chip was dipped in a developer to develop the written pattern. After the development, 6-nm Pt and 8-nm Au were deposited on the surface of the chip through vapor evaporation. After the deposition, the chip was dipped in acetone to remove the resist, and then rinsed by dipping it in isopropyl alcohol.

(4) Dispersion of Nanotubes:

Multi-layered carbon nanotubes (from Shinku Yakin) were dispersed in a dichloroethane solution to prepare a dispersion. Then, the resulting dispersion was dropwise applied onto the chip with the address pattern formed thereon in the above (3), by the use of a syringe. Before completely dried up, the dispersion applied to the chip was sucked up with the syringe. Thus sucked up, the dispersion was completely removed from the chip. Next, the chip was rinsed with isopropyl alcohol, and then heated in an oven at 100° C. for 5 minutes. Through the process, the carbon nanotubes were dispersed on the chip.

(5) Formation of Contact to Nanotubes:

The chip with the carbon nanotubes dispersed thereon in the above (4) was observed with an electronic microscope (Hitachi's S-5000) (not shown). The chip had the address pattern formed in the part thereof not having the lead electrode. Accordingly, the electromicroscopic observation confirmed both the address pattern and the dispersed nanotubes formed on the chip. Thus observed, the relative positional relationship between the address pattern and the carbon nanotubes was recorded. This corresponds to recording where the carbon nanotubes are positioned on the chip. Preferably, the carbon nanotubes for use herein are so selected that they have a length of at least 5 μm, more preferably from 5 to 90 μm. Next, based on the thus-recorded data, the wiring pattern to connect the carbon nanotubes and the lead electrode formed in the above (2) was planned. Using the thus-planned pattern, the carbon nanotubes and the lead electrode were wired with a metal, in the same manner as in the above (3). For the wiring, Pt and Au were used in the same manner as in the above (3). The thickness of Pt was from 5 nm to 10 nm, and that of Au was from 30 to 50 nm. Thus using Pt and Au makes it possible to form an ohmic contact to the multi-layered carbon nanotubes.

The chip with the carbon nanotubes wired to the lead electrode that had been fabricated in the above was set to a prober (Nippon Micronics' 708 fT-006), in which the electric conductivity of the carbon nanotubes was measured. The prober had 4 probes, one of which was led to the part having the same potential as that of the back-gate electrode and two were to the lead electrode of the chip. The probes were connected to a parameter analyzer (HP 4156A). The electric conductivity of the carbon nanotubes was measured, and the data were recorded. FIG. 5 shows a schematic view of the device fabricated herein.

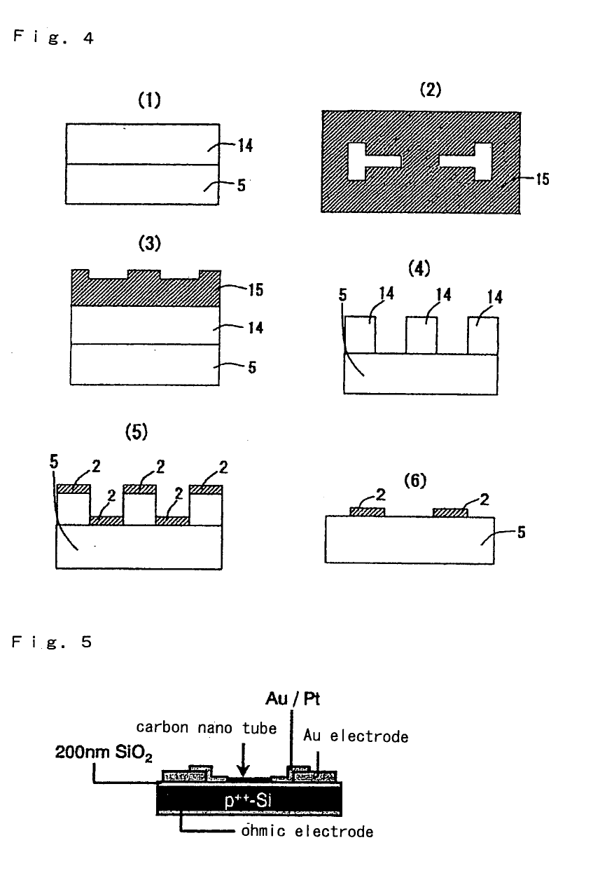

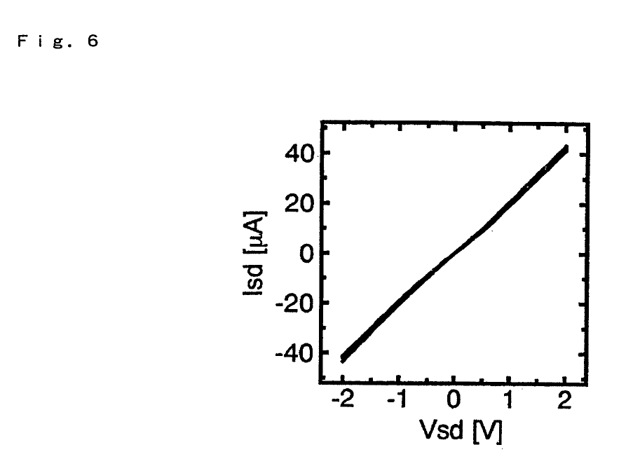

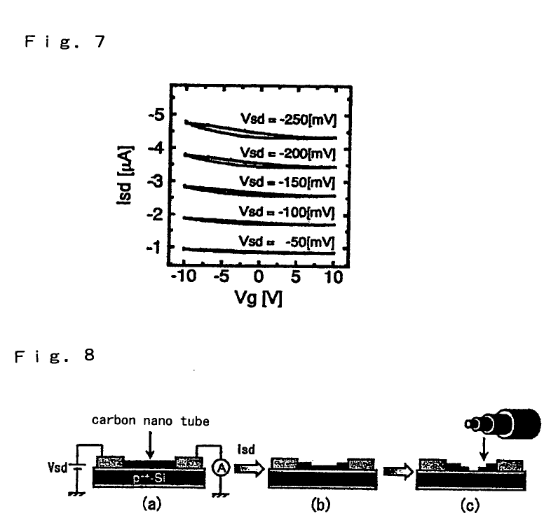

FIG. 6 shows a current-voltage curve. For the current-voltage curve, a prober (from Nippon Micronics) was employed (the same shall apply hereinunder). In FIG. 6, Isd indicates the current between source-drain; and Vsd indicates the voltage between source-drain (the same shall apply hereinunder). The device generated a maximum current of tens μA at a low voltage (at most 2 V), and gave no hysteresis. FIG. 7 shows the data of current-voltage curve relative to the gate electrode. In FIG. 7, Vg indicates the voltage of the gate electrode (the same shall apply hereinunder). FIG. 7 confirms that the current does not depend on the gate voltage. This means that the carbon nanotubes behave like metal.

(6) Electric Breakaway of Nanotubes:

After the electric conductivity thereof was measured as in the above (5), the carbon nanotubes were exposed to a few volts with a high-density current (0.1 to 0.2 mA) applied thereto, and the current was kept applied thereto for a predetermined period of time (at most 300 seconds). In this stage, the current value passing through the carbon nanotubes stepwise decreased, and finally it became zero. The reason why the current became zero is because the center part of the carbon nanotubes were cut off owing to the high-density current passing through them. In this operation, the center part of the carbon nanotubes connected to the lead electrode was cut off. The carbon nanotubes with the center part thereof cut off were observed with an electronic microscope in the same manner as in the above (5), and the length of the cut part L was at most 50 nm. These schematic views are FIG. 8 and FIG. 9.

FIG. 8 shows the electrically-broken condition of the carbon nanotubes. FIG. 9 shows the condition of the device of FIG. 8(a) with gradually-increasing voltage applied thereto. As in FIG. 9, when the device was kept under a constant high voltage, then the quantity of current passing through the nanotubes stepwise decreased. With that, the multi-layered carbon nanotubes were broken at one by one layer and removed (FIG. 8(b)). After all the layers were broken away (FIG. 8(c)), no current run through the carbon nanotubes. In FIG. 9, the down-facing arrows each show a breaking point at which the multi-layered carbon nanotubes were broken at one by one layer. In this stage, the cut part of the nanotubes finally had a small gap. The gap as referred to herein means a fine space formed through the breakdown of the multi-layered carbon nanotubes. FIG. 10 shows the data of the length of the gap. For this, 49 samples were tried.

(7) Formation of Organic Channel:

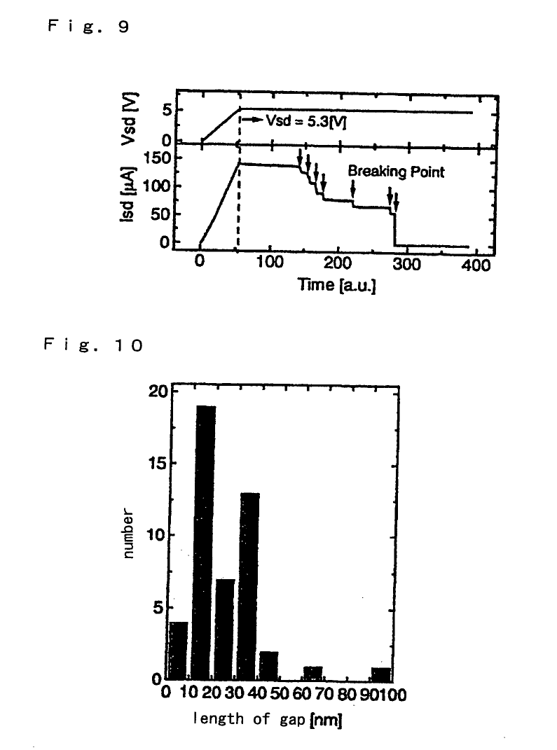

Thus processed in the above step (6), an electron-beam resist was applied to the chip in the same manner as in the above (3). After the coating, a rectangular electron-beam pattern having a length of one side of from 1 to 2 μm or so was designed for the area around the cut part of the carbon nanotubes processed in the above (6). A rectangular pattern having a length of one side of 100 μm or so was also designed for the area above the lead electrode. The two patterns were written on the device through exposure to electron beams in the same manner as in the above (3), and they were developed. After the development, a rectangular window having a length of one side of from 1 to 2 μm was formed in the area around the cut part of the carbon nanotubes. In the same manner, a rectangular window having a length of one side of 100 μm or so was also formed in the area above the lead electrode. As so mentioned hereinabove, since the length of the carbon nanotubes was larger than the size of the window formed in the cut part, it was considered that the window would be open in the area of the cut part of the carbon nanotubes. No window was formed on the metal wiring to connect the carbon nanotubes and the lead electrode. Next, of those formed in the above, the window formed above the lead electrode was carefully masked with aluminium foil. Thus masked, the chip was put into a vacuum evaporation chamber (from Ulvac) for organic material deposition, in which an organic substance was deposited on the chip through vacuum evaporation. The organic substance to be deposited herein was pentacene having a structure of five 6-membered carbon rings connected in series (from Aldrich Products). Pentacene was deposited on the cut carbon nanotubes via the windowed part thereof, whereby the cut faces of the carbon nanotubes were again connected. After the organic substance deposition, the masking aluminium foil was removed to be the device of this example. FIG. 11 shows a schematic view of this example. In this, 11 indicates the thermal oxide film of SiO₂; 12 indicates the p-type Si substrate; 13 indicates the lead electrode; 16 indicates the pentacene; and 3 indicates nanotubes.

(8) Determination of Electric Property of Fabricated Device:

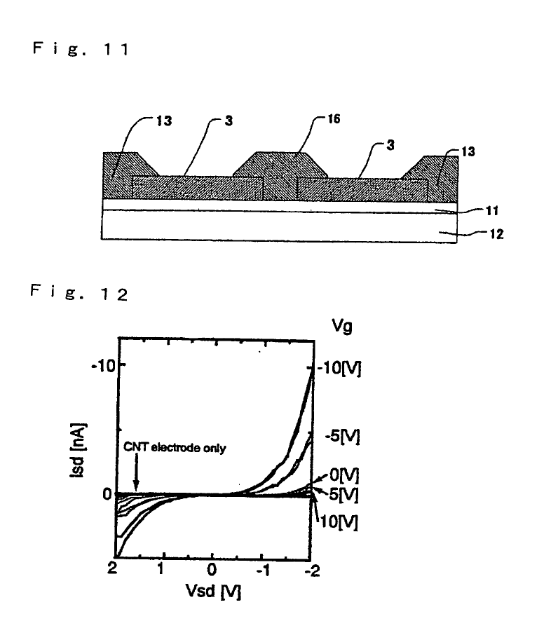

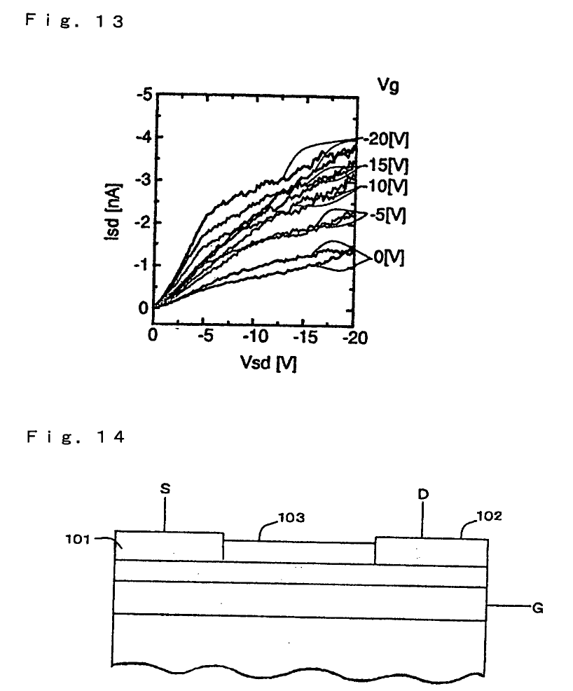

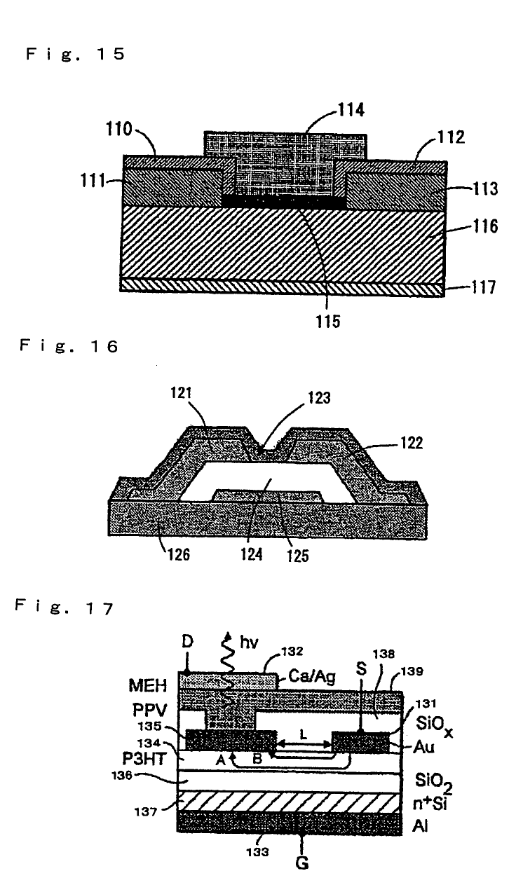

For determining the electric property of the device fabricated herein, the same prober as in the above (5) was used. In this stage, one probe of the prober was led to the part having the same potential as that of the back-gate electrode and the remaining two were to the lead electrode through the window formed on the lead electrode in the above (7). Since the non-windowed part of the lead electrode was masked with a high-insulation electron-beam resist, the probe, even if led to the non-windowed part thereof, could not be electrically connected to the lead electrode. Thus arranged, the device was checked for the electric property thereof, and electric conduction through the device was admitted. Since no electric conduction was admitted after the breakaway of the carbon nanotubes as in the above, (6), the current value measured herein means that the carbon nanotubes serve as an electrode and the current runs through the organic channel. The data are in FIG. 12.

The experiment for FIG. 12 was effected at varying gate voltages of −10 V, −5 V, 0 V, 5 V and 10 V. Before the pentacene deposition, no current run at all (CNT electrode only). As opposed to this, electric conduction was admitted after the pentacene deposition. Further, even though the source-drain voltage was low, a current of nA order run through the device. In addition, the device gave little hysteresis. In FIG. 12, when Vsd is 0 or less, the curves indicate Isd at −10 V, −10 V, −5 V, −5 V, 0 V, 0 V, 5 V, 5 V, 10 V, 10 V in that order from the bottom. When Vsd is more than 0, the curves indicate Isd at −10 V, −10 V, −5 V, −5 V, 0 V, 0 V, 5 V, 5 V, 10 V, 10 V in that order from the top. FIG. 13 shows current-voltage curves of a device with an electrode of metal alone. In FIG. 13, the curves at Vds of −20V indicates Isd at −20 V, −20 V, −15 V, −15 V, −10 V, 10 V, −5 V, −5 V, 0 V, 0 V in that order from the top.

As in the above, the invention employs a substance having 6-membered carbon rings for both the carbon nanotube and the channel. Therefore, the overlapping of the atomic orbital between the adjacent multiple-bonded atoms that are known as conjugated atoms has enabled charge transfer through the device of the invention. Specifically, the carbon nanotube disposed between metal and organic material in the device of the invention has remarkably improved the electric conductivity of the device.

The present disclosure relates to the subject matter contained in Japanese Patent Application No. 154841/2003 filed May 30, 2003, which is expressly incorporated herein by reference in its entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A terminal for an organic material, which comprises a carbon nanotube to be in contact with an organic material having a 6-membered carbon ring, and a metal that is in contact with a part of the carbon nanotube.

2. A thin-film transistor comprising, as an electrode thereof, a terminal that comprises a carbon nanotube to be in contact with an organic material having a 6-membered carbon ring, and a metal that is in contact with a part of the carbon nanotube.

3. A thin-film transistor comprising at least a first electrode region, a second electrode region, and a channel formed of an organic material having a 6-membered carbon ring for electrically connecting the first electrode region and the second electrode region, wherein the first electrode region and the second electrode region each comprise a carbon nanotube that is in contact with the 6-membered carbon ring of the channel at its interface, and a metal that is in contact with a part of the carbon nanotube.

4. A thin-film transistor comprising a substrate, an insulation layer formed on the substrate, a first electrode region, a second electrode region and a channel formed of an organic material having a6-membered carbon ring for electrically connecting the first electrode region and the second electrode region, wherein the first electrode region, the second electrode region and the channel are formed on the insulation layer, and the first electrode region and the second electrode region each comprise a carbon nanotube that is in contact with the 6-membered carbon ring of the channel at its interface, and a metal that is in contact with a part of the carbon nanotube.

5. The thin-film transistor as claimed in claim 3, wherein the carbon nanotube contains a fullerene.

6. The thin-film transistor as claimed in claim 3, wherein the carbon nanotube contains a C₆₀, C₇₀, C₇₆, C₇₈, C₈₂, C₈₄ or C₉₂ fullerene.

7. The thin-film transistor as claimed in claim 3,wherein the carbon nanotube has a resistance of from 10⁻⁵ to 10⁻⁴ Ωcm.

8. The thin-film transistor as claimed in claim 3, wherein the channel is formed of an acene.

9. The thin-film transistor as claimed in claim 3, wherein the channel is formed of a thiophene or a fullerene.

10. The thin-film transistor as claimed in claim 3, wherein the channel is formed of pentacene.

11. The thin-film transistor as claimed in claim 3, wherein the carbon nanotube is a multi-layered one.

12. The thin-film transistor as claimed in claim 3, wherein the metal that is in contact with a part of the carbon nanotube is gold, titanium, chromium, thallium, copper, titanium, molybdenum, tungsten, nickel, palladium, platinum, silver or tin, or a combination thereof.

13. The thin-film transistor as claimed in claim 3, wherein the metal that is in contact with a part of the carbon nanotube is a combination of gold and platinum.

14. The thin-film transistor as claimed in claim 3, wherein the contact length between the channel and the carbon nanotube is from 1 to 10 μm.

15. The thin-film transistor as claimed in claim 3, wherein the length of the carbon nanotube is from 5 to 20 μm.

16. The thin-film transistor as claimed in claim 4, wherein the insulation layer is formed of an inorganic material, a polymer material or a self-organizing molecular membrane.

17. The thin-film transistor as claimed in claim 4, wherein the substrate is an insulating substrate or a semiconductive substrate.

18. The thin-film transistor as claimed in claim 4, wherein the first electrode region and the second electrode region have two or more carbon nanotubes each.

19. The thin-film transistor as claimed in claim 4, wherein the carbon nanotube contained in the first electrode region and the carbon nanotube contained in the second electrode region are parallel to each other in the area in which they are in contact with the channel.

20. A method for producing a thin-film transistor, which comprises a step of forming a first metal electrode and a second metal electrode on a substrate, a step of dispersing carbon nanotubes so as to form an electroconductive structure between the first metal electrode and the second metal electrode, a step of cutting a part of the carbon nanotubes through electric breakaway, and a step of forming a channel of an organic material on the carbon nanotubes that include the cut part thereof.
